(19) United States
(12) Patent Application Publication
(10) Pub. No.: US 2025/0105391 A1
(43) Pub. Date: Mar. 27, 2025

(54) SUPPORT FOR DIELECTRIC FLUID CIRCUIT AND CORRESPONDING THERMAL REGULATION ASSEMBLY, IN PARTICULAR FOR A MOTOR VEHICLE

(71) Applicant: VALEO SYSTEMES THERMIQUES, Le Mesnil-Saint-Denis (FR)

(72) Inventors: Julien Tissot, Le Mesnil-Saint-Denis (FR); Kamel Azzouz, Le Mesnil-Saint-Denis (FR); Moussa Nacer Bey, Le Mesnil-Saint-Denis (FR); Sebastien Garnier, Le Mesnil-Saint-Denis (FR)

(73) Assignee: VALEO SYSTEMES THERMIQUES, Le Mesnil-Saint-Denis (FR)

(21) Appl. No.: 18/728,550

(22) PCT Filed: Jan. 12, 2023
(86) PCT No.: PCT/EP2023/050647

§ 371 Date: Jul. 12, 2024

(30) Foreign Application Priority Data
Jan. 14, 2022 (FR) FR2200319

(51) Int. Cl. H01M 10/625; B60R 16/08; H01M 10/613; H01M 10/6568

(52) U.S. Cl. CPC H01M 10/625; B60R 16/08; H01M 10/613; H01M 10/6568; H01M 2220/20

(57) ABSTRACT

A support for a dielectric fluid circuit is for a thermal regulation assembly. The assembly includes a housing formed by a container open on a side that defines a recess and is configured to be closed by a lid. The recess is configured to receive at least one electric component. The support includes a number of nozzles for spraying a dielectric fluid. The support defines a pipe for the circulation of the dielectric fluid and the pipe is configured to supply the spray nozzles with dielectric fluid. The support is configured to be arranged and held in the housing between the component and the lid.

The present invention relates to a support for a dielectric fluid circuit for a thermal regulation assembly, in particular in the automotive field. Such an assembly comprises a plurality of electrical and/or electronic components capable of releasing heat when they are operating. The dielectric fluid circuit support comprises a predetermined number of nozzles allowing the thermal regulation of these components by spraying dielectric fluid.

The components to which the present invention relates can be electrical energy storage elements, in particular battery elements, or power electronics elements, for example but not limited to semiconductors such as diodes or transistors. They could also be components of computer servers.

The invention is advantageously applicable in the field of the thermal regulation of a power electronics device or module, that is, comprising power electronics components. During operation, the temperature of such a power electronics device or module can rise, with the risk of damage to some of the power electronics components.

The invention is also advantageously applicable in the field of the thermal regulation of an electrical energy storage device, such as a battery assembly or battery pack for an electric and/or hybrid motor vehicle. The electrical energy for electric and/or hybrid vehicles is supplied by one or more batteries. During operation, the electrical energy storage elements such as batteries heat up and thus risk being damaged. In particular, one charging technique, referred to as rapid charging, consists of charging the energy storage elements at a high voltage and high amperage for a short time, in particular a maximum time of about twenty minutes. Such rapid charging causes the electrical energy storage elements to heat up significantly, which must be managed.

In the field of motor vehicles, it is known practice to use a thermal regulation device, in particular for cooling electrical energy storage components for example, such as batteries. Such a thermal regulation device makes it possible to modify a temperature of an electrical energy storage device, for example during starting of the vehicle in cold weather, by increasing its temperature for example, or when traveling or during an operation to recharge said system, by decreasing the temperature of the battery elements, which tend to heat up when they are being used.

According to one known solution, the thermal regulation device comprises a cold plate inside which a coolant circulates and which is arranged in contact with the components to be cooled. It has been found that such an arrangement can lead to non-uniform cooling of the components of a single device to be cooled, for example an electrical energy storage device, leading to a decrease in the overall performance. Such a thermal regulation device also has high thermal resistance because of the thicknesses of material present between the coolant and the elements to be cooled. In addition, this solution generally has a large footprint.

According to another known thermal regulation solution, in particular for cooling components such as battery elements, a dielectric fluid is sprayed directly onto the components received in a housing by means of a dielectric fluid circuit and orifices or nozzles for spraying the dielectric fluid. A heat exchange can then take place between the components and the dielectric fluid that comes into direct contact with a surface of the components.

One enduring problem relates to the incorporation of the dielectric fluid circuit and the spray nozzles so that dielectric fluid can be sprayed onto the components received in the housing in an efficient manner.

In the known solutions, a plurality of pipes is provided in order to allow the dielectric fluid to circulate inside the housing, passing in particular through the walls of the housing in order to allow the dielectric fluid to enter and leave the housing. However, assembly can be complicated as a result of this multiplicity of pipes, which must be secured relative to the walls of the housing so that they do not come into contact with the electrical or electronic components before the fluid is sprayed.

To overcome this drawback, it has been proposed to form a plurality of pipes for the circulation of the dielectric fluid in the lateral walls of the housing receiving the components. However, such a solution requires considerable modification of the housing of a battery pack, for example, and is not easy to apply to different types of battery pack.

The invention falls within this context and aims to provide an alternative to the known thermal regulation assemblies, in particular in their application to electrical storage devices such as motor vehicle batteries, that overcomes the aforementioned problems, inter alia.

To this end, the invention relates to a support for a dielectric fluid circuit for a thermal regulation assembly, said assembly comprising a housing formed by a container open on at least one side, defining a recess and intended to be closed by a lid, this recess being configured to receive at least one electronic and/or electrical component for thermal regulation.

The support comprises a predetermined number of nozzles for spraying a dielectric fluid.

The support defines at least one pipe for the circulation of the dielectric fluid, configured to supply the spray nozzles with dielectric fluid.

The support is configured to be arranged and held in the housing between said at least one component and the lid.

Such a support can thus be added and incorporated easily into different types of housing, in particular battery packs. It can be completely separate from the housing, requiring no modification of the battery pack, for example. It can also be separate from the open container receiving the components for thermal regulation, and be incorporated into the lid, which minimizes the modifications of the battery pack, for example.

The dielectric fluid support can further comprise one or more of the following features described below, taken separately or in combination.

The support can define a plurality of dielectric fluid circulation pipes, for example parallel to each other.

The spray nozzles can be made in one piece with the support.

Alternatively, the nozzles can be added and fastened to the support, for example by clipping or screwing, in particular at the connection points.

At least some nozzles can be arranged so as to allow dielectric fluid to be sprayed tangentially onto the component(s) for thermal regulation, for example.

As a variant or in addition, at least some nozzles can be arranged so as to allow dielectric fluid to be sprayed directly onto the component(s) for thermal regulation, or alternatively toward the lid.

The support can have the general shape of a frame. The frame is shaped to correspond at least to the perimeter or peripheral edge of the lid and/or of the container defining the recess for said at least one electronic and/or electrical component.

At least some spray nozzles can be arranged on a longitudinal and/or lateral edge of the frame.

The support can comprise at least one crossmember connecting two opposite edges of the frame.

Said at least one crossmember can define said at least one pipe for the circulation of the dielectric fluid.

At least one spray nozzle can be arranged on said at least one crossmember.

According to one embodiment, at least two spray nozzles can be arranged on either side of a common crossmember.

The support can comprise at least one retaining or fastening element for holding the crossmember in the housing.

The support can comprise at least one element for fastening it in the housing.

The support can comprise at least one sealing element.

The support can comprise at least one dual-purpose element for sealing and fastening the support in the housing.

By way of example, the support can comprise at least one peripheral sealing lip positioned along the support.

The sealing lip can be configured to be arranged between the lid and the container.

The sealing element such as the peripheral lip can be made from an elastomeric material.

The support can comprise at least a first part and a second part, assembled together. The first part and the second part can be assembled by overmolding.

The first and second parts can together define at least one pipe.

At least one of the first and second parts can have a predetermined number of points for connecting the spray nozzles. The connection points are in fluidic communication with said at least one pipe.

At least one of the first and second parts can have orifices forming the connection points configured to receive the spray nozzles. These orifices emerge in the or at least one pipe. As a variant, the nozzles can be molded in said part.

According to a first embodiment, the support is made separately from the housing for receiving the support.

The support can be separate from the lid.

The support can be separate from the open container.

The support can comprise at least one element for fastening to the housing.

The support can be fastened directly to the lid and/or to the container closed by the lid. As a variant, the support can be fastened to a rib extending from the lid or a wall of the container. This rib is for example integrally formed with the lid or the wall of the container.

The fastening element can be configured for fastening by clamping or wedging, by clipping, by screwing, by interaction with a complementary fastening element on the housing, or by any other type of fastening.

The fastening element or at least one fastening element can be positioned along a peripheral edge of the support in the shape of a frame for example, or all around the frame.

The support can comprise at least one additional member, selected from at least one suction pump, at least one heat exchanger, at least one filter, and at least one sensor.

The support can comprise an ancillary zone configured for the fluidic connection of said at least one pipe to the at least one additional member.

The heat exchanger is for example a chiller for the circulation of a coolant, so as to allow the cooling of the dielectric fluid by heat exchange with the coolant.

As a variant or in addition, the heat exchanger can be a radiator.

The or at least one sensor can be a pressure sensor.

The or at least one sensor can be a temperature sensor.

The ancillary zone also allows the mechanical connection of the additional member or members.

The ancillary zone can comprise:
at least one channel fluidically connected to a dielectric fluid outlet of said pump and to a dielectric fluid inlet of said heat exchanger, so as to allow the cooling of the dielectric fluid, and/or
at least one channel fluidically connected to a dielectric fluid outlet of said pump or of said heat exchanger and emerging in said filter, so as to filter the dielectric fluid, and/or
at least one channel made at the outlet of the filter or of said heat exchanger or of the suction pump, and fluidically connected to said at least one pipe.

According to a second embodiment, the support is made in one piece with the lid.

The support can be incorporated into the lid by overmolding.

The support can be at least partially, or even completely, embedded in the material forming the lid.

The spray nozzles can respectively comprise at least one spray orifice arranged to that it sprays at least one jet of dielectric fluid toward said at least one component and/or toward the lid, in the assembled state of the support in the housing.

At least one nozzle can comprise a plurality of orifices arranged so that they respectively spray at least one jet of dielectric fluid toward different surfaces of said component and/or of the lid.

According to one particular exemplary embodiment, at least one nozzle comprises:
at least one first spray orifice configured to be arranged facing a gap between at least two adjacent components, so that it sprays a first jet of dielectric fluid between the two adjacent components, and
at least one second spray orifice configured to be arranged so that it sprays a second jet of dielectric fluid toward a surface of said at least one component facing the lid.

The support can be made from a composite plastic material, advantageously heat resistant.

According to one variant, when the support is separate from the housing, it can be at least partially made from metal.

The invention also relates to a thermal regulation assembly. This assembly can be intended to be provided on a vehicle, in particular a motor vehicle.

The thermal regulation assembly comprises a housing formed by a container open on at least one side, defining a recess and intended to be closed by a lid, the recess receiving at least one electronic and/or electrical component for thermal regulation. The housing incorporates at least one dielectric fluid circuit support as described above.

At least one additional member for the operation of the dielectric fluid circuit and the spray nozzles, such as at least one suction pump, at least one heat exchanger, such as a chiller, and at least one filter, can be received inside the housing, for example in an ancillary zone of the support.

The thermal regulation assembly can comprise at least one sealing element positioned between the lid and the facing peripheral edge of the container receiving said at least one component.

The invention can further relate to a battery pack forming a thermal regulation assembly as defined above. Such a battery pack comprises a plurality of energy storage cells and at least one dielectric fluid circuit support incorporated into the battery pack and comprising a predetermined number of dielectric fluid spray nozzles arranged so that they wet the plurality of energy storage cells.

Further advantages and features of the invention will become more clearly apparent on reading the following description, given by way of illustrative and non-limiting example, and the appended drawings, in which:

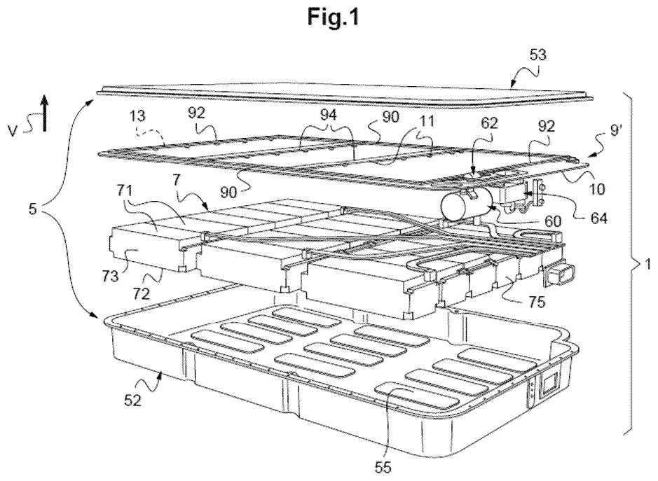

FIG. 1 is an exploded view of a thermal regulation assembly comprising components for thermal regulation and a dielectric fluid circuit support for the thermal regulation of the components according to a first embodiment.

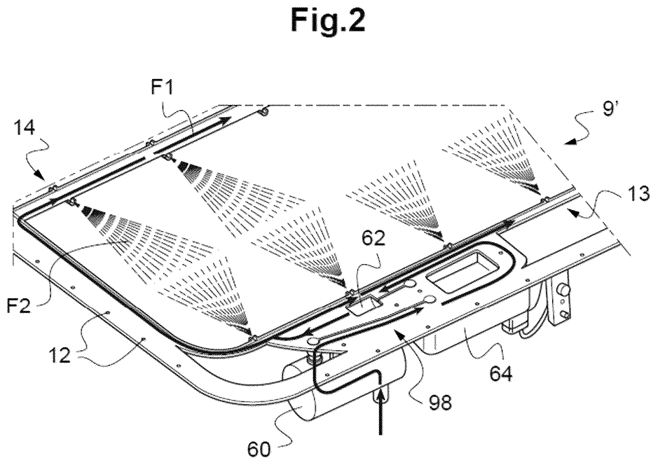

FIG. 2 is a partial perspective view of the dielectric fluid circuit support in FIG. 1.

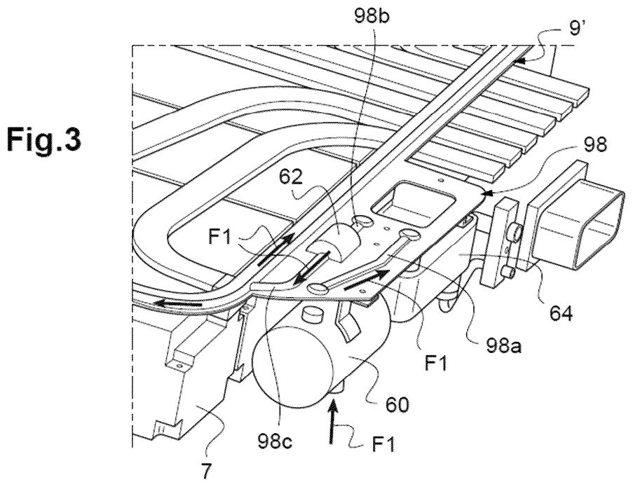

FIG. 3 shows an enlarged view of a portion of the dielectric fluid circuit support in FIG. 1.

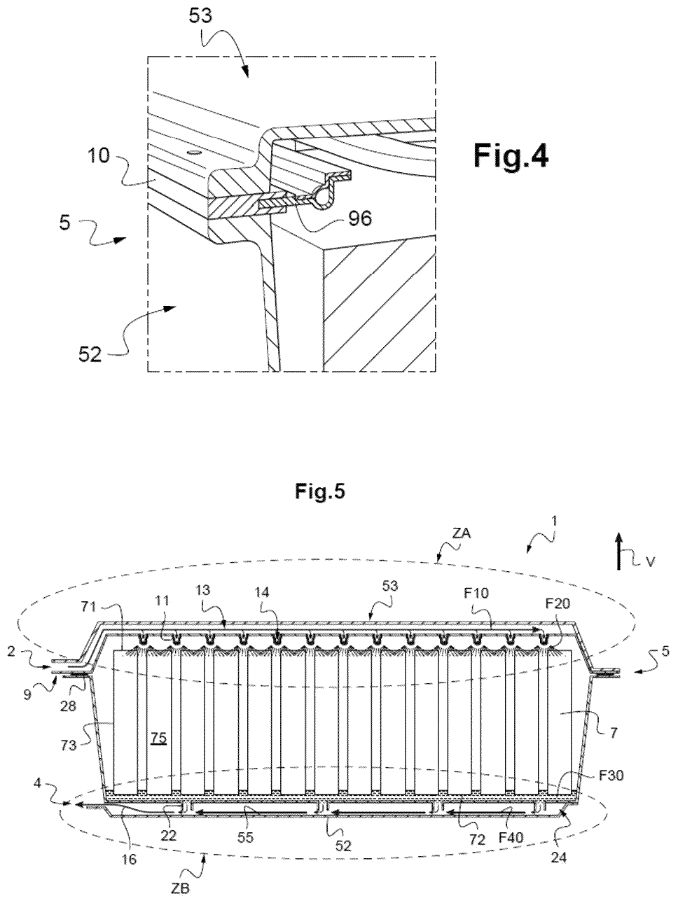

FIG. 4 is a cross-sectional view of a portion of the assembly in FIG. 1 after assembly.

FIG. 5 schematically shows a thermal regulation assembly comprising a dielectric fluid circuit support incorporated into a lid arranged facing the components for thermal regulation according to a second embodiment.

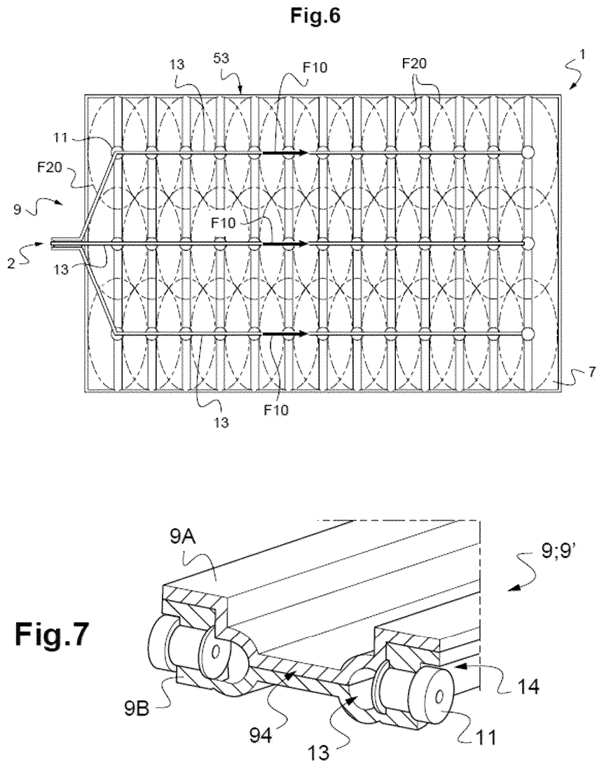

FIG. 6 is a cross-sectional top view of the assembly in FIG. 5.

FIG. 7 shows an enlarged view of a portion of the dielectric fluid circuit support according to one exemplary embodiment with two assembled parts defining a dielectric fluid circulation pipe.

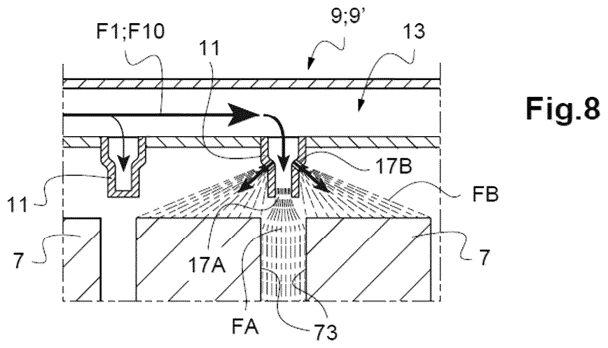

FIG. 8 schematically illustrates a particular exemplary embodiment of a multi-jet nozzle.

In the figures, identical elements have the same reference numbers.

The following embodiments are examples. Although the description refers to one or more embodiments, this does not necessarily mean that each reference sign relates to the same embodiment, or that the features only apply to a single embodiment. Individual features of different embodiments can also be combined or interchanged in order to create other embodiments.

In the description, certain elements can be given ordinal numbers, for example first element or second element. In this case, the ordinal number is simply to differentiate and denote elements that are similar but not identical. This ordinal numbering does not imply that one element takes priority over another and such numbering can easily be interchanged without departing from the scope of the present invention. Likewise, this ordinal numbering does not imply any chronological order.

### Thermal Regulation Assembly

The invention relates to a thermal regulation assembly 1, which can be intended to be provided on a vehicle, in particular a motor vehicle. A first embodiment is shown schematically in FIGS. 1 to 4. A second embodiment is shown schematically in FIGS. 5 and 6.

The thermal regulation assembly 1 can comprise a housing 5, for example having a generally parallelepipedal shape.

More specifically, this housing 5 can comprise a tray or container 52 open on at least one side, and a lid 53 that closes the housing 5 when it is assembled with the container 52. Advantageously, at least one sealing element can be positioned between the lid 53 and a facing peripheral edge of the container 52. The sealing element can be made from an elastomeric material.

Generally, the thermal regulation assembly 1 comprises one or more electrical or electronic components the temperature of which must be regulated, for example reduced. More precisely, the thermal regulation assembly 1 can comprise one or more modules 7, in particular for electrical storage, comprising the electronic and/or electrical component(s).

By way of non-limiting example, the thermal regulation assembly 1 can be a battery pack comprising a plurality of modules 7, such as energy storage modules or cells, the temperature of which is regulated by the thermal regulation device 3.

Here, a module 7 can be an energy storage cell. As a variant, a module 7 can comprise a plurality of energy storage cells. A module 7 can further be defined as a container or housing comprising one or more electronic and/or electrical components. The module 7 can be closed. It can be a group of cells, for example in an element forming a lid or cover on an upper part of the thermal regulation assembly 1 or of a battery pack.

In the examples illustrated, the components or modules 7 are shown schematically with a generally parallelepipedal shape. This parallelepipedal shape has a length, a width, and a height. Of course, any other shape can be envisaged.

The modules 7 respectively have an upper face 71 and an opposite lower face 72, connected by lateral faces 73, 75.

The housing 5 is intended to receive the component(s) or module(s) 7. To this end, the container 52 has an inner volume defining a recess in which the components or modules 7 can be positioned. The components or modules 7 can be positioned in a row or several rows. These rows are advantageously positioned parallel to one another.

The upper face 71 of at least one component or module 7 can be intended to be arranged facing the lid 53. The lower face 72 can be intended to be arranged against a bottom wall 55 of the container 52.

By way of example, the upper face 71 and opposite lower face 72 extend in the direction of the length and width of a component or module 7. Two first lateral faces 73 are for example two opposite large lateral faces extending in the direction of the length and height of the component or module 7. Two second lateral faces 75 are for example two opposite small lateral faces extending in the direction of the width and height of the component or module 7.

The temperature of the component(s) or module(s) 7 is intended to be thermally regulated by spraying dielectric fluid onto one or more surfaces.

The surface(s) of a module 7 to be wetted by the dielectric fluid can be flat or substantially flat.

As a variant, a surface to be wetted can be curved or convex, with a convexity oriented toward the outside of the component or module 7. The curvature of this surface to be wetted makes it possible to facilitate the flow of the dielectric fluid toward the surfaces of the lateral faces, which extend vertically with reference to the orientation of the example in FIG. 1 or FIG. 5. It can also be envisaged that the surface to be wetted is inclined relative to a horizontal or vertical plane with reference to the orientation of the thermal regulation assembly 1 after final assembly.

The thermal regulation assembly 1 additionally comprises at least one dielectric fluid circuit support 9, 9′, hereinafter referred to as the support 9, 9′.

The support 9, 9′ can be arranged and held in the housing 5 between the component(s) or module(s) 7 and the lid 53. On final assembly of the thermal regulation assembly 1, the support 9, 9′ is interposed between the components or modules 7 received in the container 52 and the lid 53 or a wall of the lid 53.

Such a support 9, 9′ incorporates a dielectric fluid circuit and comprises a predetermined number of nozzles 11 for spraying dielectric fluid, so as to allow the thermal regulation of the component(s) or module(s) 7. The support 9, 9′ and the elements comprising it are described in greater detail below.

The flow of the dielectric fluid in the support 9, 9′ can be controlled by means of at least one member for circulating the dielectric fluid, such as a pump. A reservoir for storing the dielectric fluid can also be provided. The circulation of the dielectric fluid is indicated by the arrows F1 (FIGS. 2, 3) and F10 (FIGS. 5, 6).

The dielectric fluid can be single-phase or two-phase. The latter is selected for example depending on its phase change temperatures.

In the case of a two-phase dielectric fluid, when it is sprayed in the liquid phase, it tends to evaporate on contact with the components or modules 7, which are for example heated during operation. The vapor can then be cooled by a cooling circuit.

In the case of a single-phase dielectric fluid, once it has been sprayed, in particular in the liquid phase, the dielectric fluid can be taken back in by a pump, for example. The dielectric fluid can optionally be conveyed to an exchanger (not shown) for cooling for example, before being reintroduced into the support 9, 9′ for the thermal regulation of the components or modules 7.

The thermal regulation assembly 1 can further comprise one or more elements or members necessary for the operation of the dielectric fluid circuit. These elements or members can be received inside the housing 5, for example being incorporated into the support 9′, in particular in an ancillary zone of the support 9′.

These can be for example, but are not limited to, one element of at least one suction pump 60, one filter 62, or at least one heat exchanger 64. Such elements are depicted in the example shown in FIGS. 1 to 3.

The suction pump 60 makes it possible to take in the dielectric fluid, for example contained in a reservoir, and direct it into the dielectric fluid circuit defined by the support 9, 9′.

By way of non-limiting example, the filter 62 can be a filter for particles in particular smaller than 5 μm. The filter 62 can filter metal particles for example. The filter 62 can comprise for example a desiccant for absorbing moisture, which can be harmful for some dielectric fluids, with the risk that it will negatively affect their dielectric properties.

The heat exchanger 64 can be a chiller, in which a heat exchange is intended to take place between a refrigerant and the dielectric fluid intended to flow in the dielectric fluid circuit. As a variant or in addition, the heat exchanger 64 or another heat exchanger could be a radiator.

It can also be envisaged to incorporate one or more sensors into the support 9′, such as pressure sensors or temperature sensors.

In addition, as shown in the example in FIG. 5, the thermal regulation assembly 1 can comprise at least one zone ZA for spraying the dielectric fluid and at least one zone ZB for recovering the dielectric fluid after spraying, in particular before it is discharged from the assembly 1.

The spraying zone ZA and the recovery zone ZB are in particular provided on either side of the components or modules 7 for thermal regulation.

In particular, the spraying zone ZA can be defined in a first region of the housing 5 and the recovery zone ZB can be defined in a second region of the housing 5. These two regions are for example opposite each other. With reference to the orientation of the elements in FIG. 6, the first region is an upper or top region of the housing 5 and the second region is a lower or bottom region of the housing 5. The terms top and bottom are defined with respect to a vertical axis V of the thermal regulation assembly 1.

The thermal regulation assembly 1 can optionally comprise, in particular in the recovery zone ZB, at least one dielectric fluid collector 16, as described hereinafter with reference to FIG. 5. This can be envisaged in particular when the dielectric fluid used for thermal regulation is a single-phase dielectric fluid.

The invention more particularly relates to the support 9, 9′, described in greater detail hereinafter, with reference to FIGS. 1 to 7.

### Dielectric Fluid Circuit Support

The support 9, 9′ is generally intended to be held fixed in the housing 5. This can be achieved by means of at least one mechanical retaining or fastening element.

The fastening element can be configured for fastening by clamping or wedging, by clipping, by screwing, by interaction with a complementary fastening element on the housing, or by any other type of fastening.

The or at least one fastening element can be positioned along the support 9, 9′.

The support can be fastened directly to the lid 53 and/or to the container 52. As a variant, the support can be fastened to a rib extending from the lid 53 for example or optionally from a wall of the container 52. This rib is for example integrally formed with the lid or optionally the wall of the container.

Alternatively, the support can be held by overmolding the support 9, 9′ on an element of the housing 5, for example on the lid 53.

The support 9, 9′ can further comprise at least one sealing element, for example made from an elastomeric material. The or at least one sealing element can be positioned along the support 9, 9′.

One sealing element can for example be fastened to the support 9, 9′ and be intended to be arranged between the lid 53 and a peripheral edge facing the container 52.

As a variant, the sealing element could be intended to be arranged and held between the support 9, 9′ and an element of the housing 5 such as a peripheral edge of the container 52.

A sealing element separate from the support 9, 9′ and intended to be arranged and held between the lid 53 and the container 52 could also be envisaged.

Advantageously, the support 9, 9′ can comprise at least one dual-purpose element for sealing and fastening the support in the housing.

The support 9 or 9′ can optionally have the general shape of a frame, as shown in the example in FIG. 1.

The frame is shaped to correspond at least to the perimeter or peripheral edge of the lid 53 and/or the container 52. The frame defines a rectangular shape the peripheral outline of which can go around all of the components or modules 7 received in the container 52. The frame has two opposite longitudinal edges 90 connected by two opposite lateral edges 92. At least one crossmember 94 can connect two opposite edges 90, 92 of the frame.

This frame shape can in particular make it possible to form a network of nozzles 11 that can be arranged facing all the way around all of the components or modules 7 of the battery pack for example.

The optional fastening and/or sealing element can in this particular example be positioned along at least one peripheral edge of the support 9, 9′ in the shape of a frame, or all around such a frame.

The support 9, 9′ can optionally comprise at least one retaining or fastening element for holding the crossmember 94 in the housing 5. The crossmember 94 can for example be fastened to a rib (not shown) extending from a wall of the lid 53, for example integrally formed therewith, and toward the support 9, 9′. Non-limitingly, it can be fastened by clipping for example.

In addition, this support 9, 9′ defines at least one pipe 13 for the circulation of the dielectric fluid, configured to supply the nozzles 11 with dielectric fluid. Such a pipe forms a supply pipe 13.

Such a pipe 13 can be defined at least partially or even all along the support 9, 9′.

For example, when the support 9, 9′ has the general shape of a rectangular frame, one or more pipes 13 can be defined by at least one edge, which can be a lateral edge 92 and/or a longitudinal edge 90, and/or by a crossmember 94.

The support 9, 9′ can define a plurality of pipes 13. At least some of these pipes 13 or even all of the pipes 13 can extend parallel to each other.

One pipe 13 can fluidically connect a plurality of nozzles 11. In other words, it is configured to direct the dielectric fluid toward each of the nozzles 11.

According to one exemplary embodiment, a plurality of pipes 13 can each make it possible to distribute the dielectric fluid to a respective series of nozzles 11. As a variant, a single pipe 13 can be provided to supply all of the nozzles 11 in series.

The support 9, 9′, and more specifically the or at least one of the pipes 13, can have one or more distribution or connection points 14 for the nozzles 11 (cf. FIGS. 2, 5, 7). A single nozzle 11 can be connected to a distribution or connection point 14. As a variant or in addition, at least two nozzles 11 can be connected to a common distribution or connection point 14.

According to a particular exemplary embodiment shown in FIG. 7, the support 9, 9′ can comprise at least a first part or upper part 9A and a second part or lower part 9B, which are assembled together.

One or both of the parts 9A, 9B can be molded. According to one advantageous variant, the material used for molding at least one of the two parts 9A, 9B can be selected so that it is compatible with a sealing function.

At least one or both of the parts 9A, 9B can be made from a plastic material, preferably a composite plastic.

The two parts 9A, 9B can optionally be assembled by clipping, overmolding, bonding or ultrasonic welding.

When they are assembled, the two parts 9A, 9B make it possible to define at least one pipe 13 between them. In other words, the pipe 13 is produced by the assembly of these two parts 9A, 9B.

In addition, at least one of these two parts 9A, 9B, for example the lower part 9B, can have a predetermined number of points 14 for connecting the spray nozzles 11. These connection points 14 are in fluidic communication with the or at least one pipe 13.

By way of example, the part such as the lower part 9B can have orifices forming the connection points 14 configured to receive the nozzles 11. These orifices emerge in the or at least one pipe 13.

In addition, the pipe 13 or at least one of the pipes 13 can be arranged so that it extends at least partially facing, in particular above, a row of components or modules 7. As a variant or in addition, the pipe 13 or at least one of the pipes 13 can be arranged facing a gap between two adjacent components or modules 7 or between two adjacent rows. The pipe 13 or at least one of the pipes 13 can also be intended to be arranged so that it extends facing a gap in the middle or substantially in the middle of one or more components or modules 7, or facing the longitudinal or lateral edges of the components or modules 7, or ridges in the case of parallelepipedal modules 7.

With respect to the nozzles 11, their number may be defined as a function of the flow rate of the dielectric fluid or the length of the dielectric fluid circuit.

The nozzles 11 are intended to be arranged so that they spray dielectric fluid directly or indirectly onto at least one surface of at least one component or module 7.

In addition, different strategies for arranging the groups of nozzles 11 can be envisaged.

One or more nozzles 11 can be intended to be arranged facing a gap between two adjacent components or modules 7, and in particular above a gap between the upper faces 71 of two adjacent components or modules 7. At least one such nozzle 11 can be arranged in line with one inter-module gap out of two for example, or in line with each inter-module gap.

The nozzles 11 can be arranged centrally or substantially centrally relative to the adjacent components or modules 7.

The dimensions of the nozzles 11, in particular their height, can be adapted, for example as a function of the internal space of the housing 5, in particular between the components or modules 7 and the lid 53.

When the components or modules 7 for thermal regulation are positioned in several rows, at least one series of nozzles 11 can be associated with each row. It can also be envisaged to arrange one or more nozzles 11 facing a gap between two rows of components or modules 7.

It can further be envisaged to arrange one or more nozzles 11 so that they spray at least one jet of dielectric fluid at least partially onto a wall of the housing 5 forming a deflector. This can for example be the lid 53.

The nozzles 11 can also be staggered so that they wet at least one surface of one or more components or modules 7.

The nozzles 11 each comprise one or more orifices for spraying the dielectric fluid. The spray orifices can optionally be formed by spray slots.

The spray orifices can have a generally ovoid shape or outline. As a variant, the spray orifices can have a generally circular shape or outline.

One or more nozzles 11 are particularly shaped so that they spray at least one jet of dielectric fluid F2 (FIG. 2), F20 (FIGS. 5, 6).

Such a jet of dielectric fluid F2, F20 can have a generally conical shape.

According to another alternative, at least one nozzle 11 is particular shaped so that it sprays at least one fan-shaped jet of dielectric fluid. Such a jet has a generally flat shape or flattened cone shape. It defines for example an opening angle greater than 90°, in particular between 100° and 180°, preferably of the order of 170°. This angle can be adjusted so that it uniformly covers an entire surface to be wetted of at least one component or module 7.

For example, at least some nozzles 11 can have a single spray orifice so that they spray a single jet of dielectric fluid F2, F20.

As a variant or in addition, at least some nozzles 11 can have at least two spray orifices so that they spray at least two jets of dielectric fluid F2, F20. Such nozzles 11 with a plurality of orifices are also referred to as multi-jet nozzles 11.

The different jets of dielectric fluid F2, F20 intended to be sprayed by a multi-jet nozzle 11 can be similar or different. They can have the same span or different spans. At least some jets of dielectric fluid, for example with a flat general shape, can be sprayed with the same opening angle or with different opening angles. At least some jets, for example with a flat general shape, can be sprayed in different parallel planes or in intersecting planes. At least some jets of dielectric fluid, for example with a conical general shape, can have different diameters. At least some jets can be intended to wet the same surface of a component or module 7, or conversely different surfaces, in particular of one or more components or modules 7.

With respect to the orientation of the nozzles 11, at least some nozzles 11 can be oriented so that they spray at least one jet of dielectric fluid F2, F20 toward a surface, referred to as the upper surface, of a component or module 7 facing the lid 53, in the assembled state of the support 9, 9′ in the housing 5. To this end, such nozzles 11 can be arranged so that their orifice or at least one of the spray orifices is arranged facing the surface of one or more components or modules 7 to be wetted. The dielectric fluid can in particular be sprayed vertically toward the component(s) or module(s) 7.

Alternatively, at least some nozzles 11 can be arranged to make it possible to spray dielectric fluid tangentially or substantially tangentially to the upper surfaces 71 of the components or modules 7.

As a variant or in addition, at least some nozzles 11 can be oriented so that they spray at least one jet of dielectric fluid F2 toward the lid 53, in the assembled state of the support 9′ in the housing 5. Such a variant can be produced when the support 9′ is produced separately from the lid 53. This makes it possible to deflect the jet of dielectric fluid toward the upper surface of at least one component or module 7 facing the lid. To this end, such nozzles 11 are arranged so that their orifice or at least one of the spray orifices is arranged facing the lid 53, toward which the initial jet of dielectric fluid must be sprayed. The initial jet of dielectric fluid can be sprayed vertically toward the lid 53.

In addition, at least one so-called multi-jet nozzle 11 can comprise a plurality of orifices arranged so that they respectively spray a jet of dielectric fluid toward different surfaces.

These can be different surfaces of the same element such as at least one component or module 7, or such as the lid 53. These can be different surfaces of a plurality of elements, for example a plurality of components or modules 7, or of at least one component or module 7 and the lid 53.

The different jets of dielectric fluid can have different sizes, spans, dimensions and angles.

This can apply equally to conical jets of dielectric fluid for example and to generally fan-shaped jets of dielectric fluid.

According to one particular embodiment shown schematically in FIG. 8, at least one multi-jet nozzle 11 comprises at least one first spray orifice 17A and at least one second orifice 17B.

The first spray orifice 17A and the second spray orifice 17B can be made at different levels on the nozzle 11. The first orifice 17A is for example further away from the support 9, 9′ and intended to be closer to the components or modules 7. Conversely, the second orifice 17B can be closer to the support 9, 9′ and intended to be further away from the components or modules 7.

In this example, the nozzle 11 is arranged facing a gap between two adjacent components or modules 7. The first orifice 17A of this nozzle 11 is for example intended to be arranged facing this gap between the two adjacent components or modules 7. The first orifice 17A can be configured to spray a first jet of dielectric fluid FA between the two adjacent components or modules 7. The sprayed dielectric fluid is intended to flow along the facing lateral faces 73 of the two adjacent modules 7.

The second orifice 17B is for example intended to be arranged or directed so that it sprays a second jet of dielectric fluid FB toward an upper surface of one or more, here two, adjacent components or modules 7.

The first orifice 17A and the second orifice 17B can be shaped so that the second jet of dielectric fluid FB has a larger span, for example a larger diameter, than the first jet of dielectric fluid FA.

Finally, a plurality of nozzles 11 can be arranged, for example mirrored, so that they spray complementary jets of dielectric fluid so as to optimize the wetting of at least one surface of one or more components or modules 7.

In addition, when there is a multiplicity of nozzles 11, they can be identical or different, have the same or a different number of spray nozzles, and have spray nozzles with the same or different open areas, for example of the same or different diameters. The nozzles 11 can be arranged with identical or substantially identical orientation, or mirrored, or in variable orientations, relative to the components or modules 7 or to a pipe 13.

A plurality of nozzles 11 or all of the nozzles 11 can be intended to be supplied in series by a common pipe 13. As a variant, at least some nozzles 11 can be supplied by branch pipes.

In addition, regardless of the arrangement and orientation of the nozzles 11 envisaged, at least some nozzles 11 can be sufficiently close to obtain an overlap of the jets of dielectric fluid F20 intended to be sprayed (as shown in the example in FIG. 6). By way of example, such an overlap can be at least 20%. This makes it possible to optimize the wetting of the components or modules 7 for thermal regulation.

In addition, when the support 9, 9′ has a frame shape, as shown in the example in FIG. 1, at least one nozzle 11 can be arranged on at least one lateral edge 92, and/or at least one longitudinal edge 90, and/or at least one crossmember 94. The nozzle or nozzles 11 positioned on a crossmember 94 can thus be arranged as close as possible to the components or modules 7.

Advantageously, at least two nozzles 11 can be arranged on either side of a common crossmember 94, as shown schematically in FIG. 7.

Advantageously, one or more nozzles 11 can be produced with a pipe 13. More generally, these nozzles 11 can be made in one piece with the support 9.

According to one particular example, the nozzles 11 can be injection molded in the material of the second part or lower part 9B in the example described with reference to FIG. 7. This method of incorporating the nozzles 11 by molding allows a significant saving in terms of space occupied and cost. It also makes it possible to increase the number of nozzles 11, thus improving the uniformity of spraying of the dielectric fluid.

Alternatively, the nozzles 11 can be separate from the pipe 13 and be fluidically connected at the distribution or connection points 14 of the pipe 13. In other words, the nozzles 11 can be added and fastened to the support 9, 9′, at the connection points 14. They can be fastened to the second part or lower part 9B in the example described with reference to FIG. 7. The nozzles 11 can for example be screwed, clipped and/or inserted, mounted by fitting into a pipe 13. The nozzles 11 can optionally be metal.

### First Embodiment: Separate Support

According to a first embodiment shown in FIGS. 1 to 4, the support 9′ can be produced by a distinct component that is mounted in the housing 5.

This support 9′ is produced separately from the housing 5 intended to receive it. The support 9′ is produced separately from the lid 53 and from the container 52 forming the housing 5.

This support 9′ can be made from a composite plastic material, advantageously heat resistant.

According to one variant, the support 9′ is at least partially made from metal.

The support 9′ comprises at least one element for fastening to the housing. In the example illustrated, this is advantageously a dual-purpose sealing and fastening element.

According to the example shown in FIG. 1, a peripheral sealing lip 10 is positioned along the support 9′. When the support 9′ has the general shape of a frame, such a sealing lip 10 can be positioned on the entire perimeter of the frame, as shown in the example in FIG. 1.

Non-limitingly, the sealing lip 10 can for example be fastened to a peripheral rib 96 along the support 9′, as shown in the example in FIG. 4.

The sealing lip 10 is also configured to be arranged between the lid 53, in particular a peripheral edge or a lid foot, and the container 52, in particular a peripheral edge or foot thereof. The sealing lip 10 is then clamped between the container 52 and the lid 53 that closes the housing 5.

Such a lip 10 both provides a seal between the container 52 and the lid 53, and a mechanical fastening for the support 9′ in the housing 5, without requiring additional fastening means.

As a variant or in addition, the support 9′ can comprise a predetermined number of fastening orifices 12 (see FIG. 2) positioned for example on a peripheral edge of the support 9′ to coincide with fastening orifices already provided for fastening the lid 53 to the container 52.

When the support 9′ has one or more crossmembers 94 as described above, it can be fastened for example by clipping onto ribs originating from, for example integrally formed with, the lid 53 or the container 52. Alternatively, supporting elements such as ribs can be molded or added to the support 9′ and fastened to the lid 53 or to the container 52, for example on a lateral wall or even a bottom wall.

The support 9′ according to the first embodiment can further comprise a zone referred to as the ancillary zone 98. This ancillary zone 98 is configured for the fluidic connection of the dielectric fluid circuit, particularly the or at least one pipe 13, to one or more additional members, such as the suction pump 60, the filter 62, and the heat exchanger 64, which are in particular necessary for the operation or advantageous for the operation of the dielectric fluid circuit and the nozzles 11. As described above, this can be at least one member out of the suction pump 60, the filter 62, and the heat exchanger 64 such as a chiller and/or a radiator, or one or more pressure or temperature sensors (FIGS. 1 to 3).

The support 9′ can bear and incorporate one or more of these additional members. The incorporation into the support 9′, and more specifically the mechanical connection of at least one or more of these members can take place in the ancillary zone 98.

The incorporation of the suction pump 60, the filter 62, and the heat exchanger 64 into the support 9′ makes it possible to arrange all of these elements connected to the dielectric fluid inside the housing 5, so as to minimize the fluidic connections to the outside. For example, only one fluidic connection for the refrigerant intended to circulate in the heat exchanger 64 such as a chiller could be provided.

The ancillary zone 98 can be substantially flat. In the example illustrated, this zone 98 forms a platform or an extension at one point of a peripheral edge, for example longitudinal or lateral, of the support 9′.

For the purposes of fluidic connection, the ancillary zone 98 can have one or more channels in which the dielectric fluid is intended to flow. The or at least one channel makes it possible to fluidically connect the additional members to each other, or to fluidically connect at least one of these additional members and the or at least one pipe 13 defined by the support 9′.

For example, at least the following can be provided:
one channel fluidically connected to a dielectric fluid outlet of the suction pump 60 and to a dielectric fluid inlet of the heat exchanger 64, and/or
one channel fluidically connected to a dielectric fluid outlet of the heat exchanger 64, or in the absence of the latter, a dielectric fluid outlet of the suction pump 60, and emerging in the filter 62, and/or
one channel made at the outlet of the filter 62, or in the absence of the filter 62, at the outlet of the heat exchanger 64, or in the absence of the heat exchanger 64, at the outlet of the suction pump 60, and fluidically connected to the or at least one pipe 13.

In the example illustrated in FIGS. 1 to 3, the support 9′ comprises at least the suction pump 60, the filter 62, and the heat exchanger 64, and the ancillary zone 98 comprises channels for connecting these elements to each other and to the or at least one pipe 13.

More specifically, the ancillary zone 98 comprises at least:
one channel 98a fluidically connecting a dielectric fluid outlet of the suction pump 60 and a dielectric fluid inlet of the heat exchanger 64 such as a chiller, in which refrigerant is intended to circulate so as to allow the cooling of the dielectric fluid,
one channel 98b made at a dielectric fluid outlet of the heat exchanger 64 and emerging in the filter 62, so as to filter the dielectric fluid, and
one channel 98c made at the outlet of the filter 62 and fluidically connected to the or at least one pipe 13.

The dielectric fluid taken in by the pump 60 is thus sent to the heat exchanger 64 for cooling before being filtered, and on leaving the filter 62, the cooled and filtered dielectric fluid is injected into the or at least one pipe 13 and circulates until it reaches various nozzles 11 intended to spray said fluid onto the components or modules 7 and/or onto the lid 53.

The support 9′ incorporates these channels 98a, 98b, 98c connecting the different members 60, 62, 64 and comprises connectors suitable for connecting these members 60, 62, 64. For example, when the support 9′ is produced by assembling at least two parts 9A, 9B, optionally molded, one of the parts can incorporate the channels 98a, 98b, 98c and the connectors.

### Second Embodiment: Support Incorporated into the Lid

A second embodiment of the support 9 is shown in FIGS. 6 and 7. Only the differences between this second embodiment and the first embodiment described above are detailed below.

According to this second embodiment, the support 9 is made in one piece with an element of the housing 5, advantageously the lid 53. It is no longer, as in the first embodiment, a distinct component that is fastened inside the housing 5.

The support 9 can be incorporated into the lid 53 by molding or overmolding. The support 9 can be at least partially, or even completely, embedded in the material forming the lid 53.

This incorporation of the support 9 into the lid 53 is particularly advantageous when the support 9 is made from a composite plastic material, preferably heat resistant.

The lid 53 incorporating the support 9 can comprise at least one inlet port 2 configured to convey the dielectric fluid into the dielectric fluid circuit. The pipe(s) 13 defined by the support 9 is/are in fluidic communication with the inlet port 2.

Additionally, at least one dielectric fluid outlet port 4 configured to discharge the dielectric fluid to the outside of the housing 5 can be provided. According to a particular example, such an outlet port 4 can be formed in the housing 5, for example at the bottom of the container 52, with reference to the orientation of the elements in FIG. 5.

A seal 28 can further be arranged and held between the lid 53 incorporating the support 9 and the facing peripheral edge of the container 52.

### Dielectric Fluid Collector

In addition, when the collector 16 is provided, it is configured to be arranged so that it collects the dielectric fluid flowing after spraying along the walls of the components or modules 7 for example. The dielectric fluid recovered in the collector 16 is indicated by the arrow F30.

The collector 16 is further fluidically connected to the outlet port 4, so as to allow the discharge of the dielectric fluid, as indicated by the arrows F40.

The collector 16 is arranged opposite the supply pipe(s) 13. In the example illustrated, it is arranged between the components or modules 7 and the bottom wall 55 of the container 52. This makes it possible to collect the dielectric fluid underneath the components or modules 7. In particular, the collector 16 extends facing the entire lower face of the components or modules 7.

Advantageously, the collector 16 can be incorporated into the housing 5, in particular at the bottom of the container 52, for example by overmolding. This can advantageously be achieved with a collector 16 made from a composite plastic material, in particular heat resistant.

Alternatively, the collector 16 could be produced separately from the housing 5. In this case, it can be assembled for example by clipping or screwing into the housing 5.

In addition, the collector 16 comprises a predetermined number of orifices 22 for discharging the dielectric fluid.

The discharge orifices 22 can be made on a face of the collector 16 referred to as the lower face, intended to be arranged facing the bottom wall of the container 52.

The number of discharge orifices 22 can be adjusted. A multiplicity of discharge orifices 22 facilitates discharge through suction by a pump.

These discharge orifices 22 are intended to be fluidically connected to the dielectric fluid outlet port 4.

In particular, the discharge orifices 22 can emerge in at least one discharge pipe 24.

The discharge pipe 24 is for example formed between the collector 16 and the bottom wall 55 of the container 52, positioned facing the discharge orifices 22.

The outlet port 4 can also emerge in said discharge pipe 24. The dielectric fluid passing through at least one of the discharge orifices 22 thus flows into said discharge pipe 24, to be discharged through the outlet port 4, for example being taken in by a pump.

In addition, according to an alternative not shown, the collector 16 can optionally have one or more slopes inclined relative to the bottom wall 55 and descending toward an associated discharge orifice 22. The collector 16 can also have at least one separating rib intended to extend between two component or modules 7.

The support 9 or 9′ can thus be added and incorporated easily into different types of housing, in particular battery packs. The support 9′ can be completely separate from the housing 5, in particular from the lid 53, or be incorporated into the lid 53, for example by overmolding.

Said support 9 or 9′ comprises the nozzles 11 and defines one or more pipes 13 making it possible to supply said nozzles 11. The dielectric fluid can then be sprayed by the nozzles 11 so that it comes into contact with or falls onto the surfaces to be wetted of the components or modules 7. Advantageously, the nozzles 11 are molded with the support 9, 9′ so that the number thereof can be increased.

In addition, when the nozzles 11 are multi-jet nozzles, the number of nozzles 11, and therefore the cost, can be reduced, while allowing uniform spraying of the dielectric fluid onto the surfaces of the modules 7.

Finally, the support 9′ can incorporate the members linked to the operation of the dielectric fluid circuit and making it possible, during operation, to distribute or even thermally condition and/or filter the dielectric fluid before circulation in the pipes 13 so as to supply the various nozzles 11. This makes it possible to minimize the connections to the outside of the housing 5.

1. A support for a dielectric fluid circuit for a thermal regulation assembly,
the assembly comprising a housing formed by a container open on at least one side, defining a recess and configured to be closed by a lid,
wherein the recess is configured to receive at least one electronic and/or electrical component for thermal regulation,
wherein:
the support comprises a predetermined number of nozzles for spraying a dielectric fluid,
the support defines at least one pipe for the circulation of the dielectric fluid, configured to supply the spray nozzles with dielectric fluid, and
the support is configured to be arranged and held in the housing between the at least one component and the lid.

2. The support as claimed in claim 1,
wherein the spray nozzles are produced in one piece with the support.

3. The support as claimed in claim 1,
wherein the support is in the shape of a frame.

4. The support as claimed in claim 3,
comprising at least one crossmember connecting two opposite edges of the frame and defining the at least one pipe for the circulation of the dielectric fluid, and
wherein at least one spray nozzle is arranged on the at least one crossmember.

5. The support as claimed in claim 1,
comprising at least one peripheral sealing lip positioned along the support and configured to be arranged between the lid and the container.

6. The support as claimed in claim 1,
comprising at least a first part and a second part,
wherein the first and second part of the support are assembled and define between them the at least one pipe, and
wherein at least one of the first and second parts comprises a predetermined number of points for connecting the spray nozzles,
wherein the connection points are in fluidic communication with the at least one pipe.

7. The support as claimed in claim 1,
wherein the support is produced separately from the housing which is configured to receive the support, and
the support comprising at least one element for fastening to the housing.

8. The support as claimed in claim 7,
further comprising:
at least one additional member, selected from at least one suction pump, at least one heat exchanger, at least one filter and at least one sensor, and
an ancillary zone configured for the fluidic connection of the at least one pipe to the at least one additional member.

9. The support as claimed in claim 8,
wherein the ancillary zone comprises at least one of:
at least one channel fluidically connected to a dielectric fluid outlet of the pump and to a dielectric fluid inlet of the heat exchanger, so as to allow the cooling of the dielectric fluid,
at least one channel fluidically connected to a dielectric fluid outlet of the pump or of the heat exchanger and emerging in the filter, so as to filter the dielectric fluid, and
at least one channel made at the outlet of the filter or of the heat exchanger or of the suction pump, and fluidically connected to the at least one pipe.

10. The support as claimed in claim 1,
wherein the support is produced in one piece with the lid.

11. The support as claimed in claim 1,
wherein the spray nozzles respectively comprise at least one spray orifice arranged so that it sprays at least one jet of dielectric fluid toward the at least one component and/or toward the lid, in the assembled state of the support in the housing.

12. The support as claimed in claim 11,
wherein at least one nozzle comprises:
at least one first spray orifice configured to be arranged facing a gap between at least two adjacent components, so that the first spray orifice sprays a first jet of dielectric fluid between the two adjacent components, and
at least one second spray orifice configured to be arranged so that the second spray orifice sprays a second jet of dielectric fluid toward a surface of the at least one component facing the lid.

13. The support as claimed in claim 1,
wherein the support is made from a composite plastic material.

14. A thermal regulation assembly for a motor vehicle,
the thermal regulation assembly comprising a housing formed by a container open on at least one side, which defines a recess and is configured to be closed by a lid,
wherein the recess receives at least one electronic and/or electrical component for thermal regulation,
wherein the housing incorporates at least one dielectric fluid circuit support as claimed in claim 1.
